(19) United States
(12) Patent Application Publication
(10) Pub. No.: US 2025/0105192 A1
(43) Pub. Date: Mar. 27, 2025

(54) SEMICONDUCTOR PACKAGE AND MANUFACTURING METHOD FOR THE SAME

(71) Applicant: Samsung Electronics Co., Ltd., Suwon-si (KR)

(72) Inventors: Tae Wook KIM, Suwon-si (KR); Jaeseong KIM, Suwon-si (KR); Jeongseok KIM, Suwon-si (KR); Yejin LEE, Suwon-si (KR); Jooyoung CHOI, Suwon-si (KR); Sangseok HONG, Suwon-si (KR)

(73) Assignee: Samsung Electronics Co., Ltd., Suwon-si (KR)

(21) Appl. No.: 18/635,296

(22) Filed: Apr. 15, 2024

(30) Foreign Application Priority Data
Sep. 27, 2023 (KR) 10-2023-0131071

(51) Int. Cl. H01L 23/00; H01L 21/762; H01L 23/498; H01L 23/522; H01L 25/00; H01L 25/18

(52) U.S. Cl. CPC H01L 24/16; H01L 21/76224; H01L 23/49822; H01L 23/49833; H01L 23/5223; H01L 24/32; H01L 24/73; H01L 25/18; H01L 25/50; H01L 2224/16225; H01L 2224/32225; H01L 2224/73204; H01L 2924/1815

(57) ABSTRACT

A semiconductor package may include a redistribution layer structure including a redistribution layer, a semiconductor chip a first surface of the redistribution layer structure, an under-bump structure disposed on a second surface of the redistribution layer structure and including a protective layer having a trench and an under-bump metal layer, an electronic element on the under-bump structure, and an underfill member filling at least a portion of a space between the under-bump structure and the electronic element and filling at least a portion of the trench, wherein, in a plan view, the trench surrounds the electronic element and may include a protrusion portion protruding outward from the electronic element in a region surrounding an edge of the electronic element.

### CROSS-REFERENCE TO RELATED APPLICATION

This application claims priority to and the benefit of Korean Patent Application No. 10-2023-0131071 filed in the Korean Intellectual Property Office on Sep. 27, 2023, the entire contents of which are incorporated herein by reference.

### BACKGROUND

### (a) Field

The present inventive concepts relate to semiconductor packages and manufacturing methods for the same.

### (b) Description of the Related Art

As electronic devices are required to be miniaturized, thinner, lighter, and more functional, various technologies are being researched to improve the performance, integration, and reliability of semiconductor packages.

When attaching electronic elements to a semiconductor package using

surface mount technology (SMT) with solder balls to improve the performance of the semiconductor chip, an underfill process is usually accompanied to improve the reliability of the electronic elements. This underfill material may bleed to the outside of the electronic elements, causing problems such as poor mounting of the electronic elements and deterioration of solder ball connection reliability.

### SUMMARY

In some example embodiments, the present inventive concepts provide a semiconductor package and/or a manufacturing method for the same capable of controlling bleeding of an underfill material.

In some example embodiments, the present inventive concepts provide a semiconductor package and/or a manufacturing method for the same capable of reducing, preventing, or preventing mounting defect of an electronic element provided to a semiconductor package, thereby improving reliability of the manufactured semiconductor package.

In some example embodiments, the present inventive concepts provide a semiconductor package/or and a manufacturing method for the same, having an advantage of improved reliability due to reduced defects based on control of bleeding of underfill material therein.

A semiconductor package may include a redistribution layer structure including a redistribution layer, a semiconductor chip on a first surface of the redistribution layer structure, an under-bump structure on a second surface of the redistribution layer structure that is an opposite surface of the first surface of the redistribution layer structure and including a protective layer having a trench and an under-bump metal layer, an electronic element on the under-bump structure, and an underfill member filling at least a portion of a space defined between the under-bump structure and the electronic element and filling at least a portion of the trench, wherein, in a plan view, the trench surrounds the electronic element, and may include a protrusion portion protruding outward from the electronic element in a region surrounding an edge of the electronic element.

A semiconductor package may include a first redistribution layer structure including a first insulation layer and a first redistribution layer, a semiconductor chip on a first surface of the first redistribution layer structure and electrically connected to the first redistribution layer, an encapsulating material encapsulating the semiconductor chip, an under-bump structure on a second surface of the first redistribution layer structure that is an opposite surface of the first surface of the redistribution layer structure, and including a protective layer having a first trench and an under-bump metal layer electrically connected to the first redistribution layer, an electronic element on the under-bump structure and electrically connected to the under-bump metal layer, and an underfill member filling at least a portion of a space defined between the under-bump structure and the electronic element and filling at least a portion of the first trench, wherein the first redistribution layer is exposed through the first trench.

A manufacturing method for a semiconductor package may include preparing a semiconductor chip, encapsulating the semiconductor chip by an encapsulating material, forming a redistribution layer structure including a redistribution layer electrically connected to the semiconductor chip on a first surface of the semiconductor chip, forming an under-bump structure on the redistribution layer structure, the under-bump structure including a protective layer having a trench and an under-bump metal layer, disposing an electronic element on the under-bump structure so as to be electrically connected to the under-bump metal layer, and forming an underfill member filling at least a portion of a space defined between the under-bump structure and the electronic element and filling at least a portion of the trench, wherein forming the under-bump structure may include forming the protective layer, forming the under-bump metal layer electrically connected to the redistribution layer on the protective layer, and forming the trench exposing the redistribution layer in the protective layer.

According to some example embodiments of the present inventive concepts, a semiconductor package and a manufacturing method for the same capable of controlling bleeding of an underfill material may be provided.

According to some example embodiments of the present inventive concepts, a semiconductor package and a manufacturing method for the same capable of reducing, minimizing, or preventing mounting defects of an provide electronic element may be provided.

According to still some example embodiments of the present inventive concepts, a semiconductor package and a manufacturing method for the same, having an advantage of improved reliability may be provided.

### BRIEF DESCRIPTION OF THE DRAWINGS

FIG. 1 is a cross-sectional view of a semiconductor package according to some example embodiments of the present inventive concepts.

FIG. 2 is an enlarged view of region A of FIG. 1 according to some example embodiments.

FIG. 3 is a bottom view of region A excluding the underfill member of FIG. 1 according to some example embodiments.

FIG. 4 is a bottom view of region A of FIG. 1 according to some example embodiments.

FIG. 5 is a cross-sectional view of a semiconductor package according to some example embodiments of the present inventive concepts.

FIGS. 6, 7, 8, 9, 10, 11, 12, 13, 14, 15, 16, 17, 18, 19, 20, 21, and 22 are manufacturing process diagrams of a semiconductor package according to some example embodiments of the present inventive concepts.

### DETAILED DESCRIPTION

The present inventive concepts will be described more fully hereinafter with reference to the accompanying drawings, in which example embodiments of the inventive concepts are shown. As those skilled in the art would realize, the described example embodiments may be modified in various different ways, all without departing from the spirit or scope of the present inventive concepts.

The drawings and description are to be regarded as illustrative in nature and not restrictive. Like reference numerals designate like elements throughout the specification.

Further, since sizes and thicknesses of constituent members shown in the accompanying drawings are arbitrarily given for better understanding and ease of description, the present inventive concepts are not limited to the illustrated sizes and thicknesses. In the drawings, the thickness of layers, films, panels, regions, etc., are exaggerated for clarity. For better understanding and ease of description, the thickness of some layers and areas is exaggerated.

Throughout this specification and the claims that follow, when it is described that an element is “coupled/connected” to another element, the element may be “directly coupled/connected” to the other element or “indirectly coupled/connected” to the other element through a third element. In a similar sense, this includes being “physically connected” as well as being “electrically connected”. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above or from below, and the phrase “in a cross-sectional view” means when a cross-section taken by vertically cutting an object portion is viewed from the side.

In addition, throughout the specification, sequential numbers such as first and second are used to distinguish a certain component from another component that is the same or similar to the certain component, and are not necessarily intended to refer to a specific component. Accordingly, a component referred to as a first component in a particular portion of the specification may be referred to as a second component in another portion of the specification.

In addition, throughout the specification, a singular reference to a component includes references to a plurality of these components, unless specifically stated to the contrary. For example, “an insulation layer” may be used to mean not only one insulation layer but also a plurality of insulation layers such as two, three, or more insulation layers.

In addition, throughout the specification, references to one surface and the other surface are intended to distinguish different surfaces from each other, and are not necessarily intended to limit it to a specific surface. Therefore, a surface referred to as one surface in a specific portion of the specification may be referred to as the other surface in another portion of the specification.

The use of the term “the” and similar demonstratives may correspond to both the singular and the plural. Operations constituting methods may be performed in any suitable order unless otherwise indicated herein or otherwise clearly contradicted by context and are not necessarily limited to the stated order.

The use of all illustrations or illustrative terms in some example embodiments is simply to describe the technical ideas in detail, and the scope of the present inventive concepts is not limited by the illustrations or illustrative terms unless they are limited by claims.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof.

Elements and/or properties thereof (e.g., structures, surfaces, directions, or the like) that are “substantially perpendicular”, “substantially parallel”, or “substantially coplanar” with regard to other elements and/or properties thereof will be understood to be “perpendicular”, “parallel”, or “coplanar”, respectively, with regard to the other elements and/or properties thereof within manufacturing tolerances and/or material tolerances and/or have a deviation in magnitude and/or angle from “perpendicular”, “parallel”, or “coplanar”, respectively, with regard to the other elements and/or properties thereof that is equal to or less than 10% (e.g., a. tolerance of ±10%).

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same. While the term “same,” “equal” or “identical” may be used in description of some example embodiments, it should be understood that some imprecisions may exist. Thus, when one element is referred to as being the same as another element, it should be understood that an element or a value is the same as another element within a desired manufacturing or operational tolerance range (e.g., ±10%).

It will be understood that elements and/or properties thereof described herein as being “substantially” the same and/or identical encompasses elements and/or properties thereof that have a relative difference in magnitude that is equal to or less than 10%. Further, regardless of whether elements and/or properties thereof are modified as “substantially,” it will be understood that these elements and/or properties thereof should be construed as including a manufacturing or operational tolerance (e.g., ±10%) around the stated elements and/or properties thereof.

When the terms “about” or “substantially” are used in this specification in connection with a numerical value, it is intended that the associated numerical value includes a manufacturing or operational tolerance (e.g., ±10%) around the stated numerical value. Moreover, when the words “about” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values or shapes should be construed as including a manufacturing or operational tolerance (e.g., ±10%) around the stated numerical values or shapes. When ranges are specified, the range includes all values therebetween such as increments of 0.1%.

As described herein, when an operation is described to be performed, or an effect such as a structure is described to be established “by” or “through” performing additional operations, it will be understood that the operation may be performed and/or the effect/structure may be established “based on” the additional operations, which may include performing said additional operations alone or in combination with other further additional operations.

Hereinafter, a semiconductor package according to some example embodiments of the present inventive concepts will be described with reference to the drawings. In the description below, the terms of upper surface, upper side, lower surface, and lower side may refer to upper surface, upper side, lower surface, and lower side with respect to a direction from a first redistribution layer structure 140 toward a second redistribution layer structure 180, respectively.

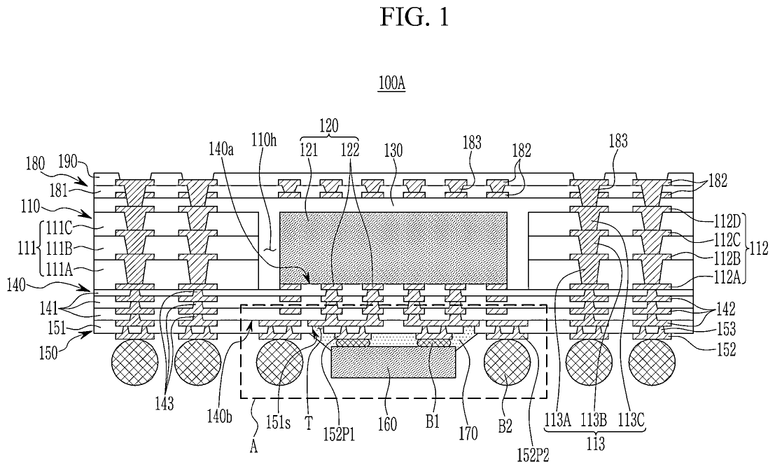

FIG. 1 is a cross-sectional view of a semiconductor package according to some example embodiments of the present inventive concepts.

A semiconductor package 100A according to some example embodiments of the present inventive concepts may include a support substrate 110 having a through-hole 110h (e.g., having one or more inner surfaces at least partially defining the through-hole 110h), a semiconductor chip 120, an encapsulating material 130, a first redistribution layer structure 140, an under-bump structure 150 including a protective layer 151 and an under-bump metal layer 152, an electronic element 160, an underfill member 170, the second redistribution layer structure 180, and a protective layer 190.

The support substrate 110 may be disposed on one surface of the first redistribution layer structure 140, and may have the through-hole 110h.

The through-hole 110h may penetrate the support substrate 110 in a thickness direction, and the semiconductor chip 120 may be disposed in the through-hole 110 h.

The support substrate 110 may include an insulation layer 111, a wire layer 112, and a via 113. For example, the support substrate 110 may include a first wire layer 112A, a first insulation layer 111A covering the first wire layer 112A, a second wire layer 112B disposed on the first insulation layer 111A, a first via 113A penetrating the first insulation layer 111A to connect the first wire layer 112A and the second wire layer 112B, a second insulation layer 111B disposed on the first insulation layer 111A to cover the second wire layer 112B, a third wire layer 112C disposed on the second insulation layer 111B, a second via 113B penetrating the second insulation layer 111B to connect the second wire layer 112B and the third wire layer 112C, a third insulation layer 111C disposed on the second insulation layer 111B to cover the third wire layer 112C, and a third via 113C penetrating a third insulation layer 111C and a fourth wire layer 112D disposed on the third insulation layer 111C to connect the third wire layer 112C and the fourth wire layer 112D.

An insulative material may be used as a material of the insulation layer 111, and for example, a thermosetting resin such as epoxy resin, a thermoplastic resin such as polyimide, pre-preg, Ajinomoto build-up film (ABF), and the like may be used. The insulation layer 111 may include a reinforcing material such as inorganic filler or glass fiber.

The insulation layer 111 may have a thicker thickness than an insulation layer 141 of the first redistribution layer structure 140 and an insulation layer 181 of the second redistribution layer structure 180, and through this, rigidity of the support substrate 110 may be increased and warpage may be controlled.

The wire layer 112 may be electrically connected to a redistribution layer 142 of the first redistribution layer structure 140 and a redistribution layer 182 of the second redistribution layer structure 180.

The support substrate 110 may have an embedded trace substrate (ETS) substrate structure, and in such a case, a circuit pattern included in the first wire layer 112A disposed lowermost among the wire layers 112 may have a buried pattern structure buried within the first insulation layer 111A. When the support substrate 110 has an ETS substrate structure, a fine circuit may be implemented, thereby reducing the number of wire layers and finely controlling the circuit line width.

The via 113 may penetrate the insulation layer 111 to interconnect the wire layers 112 disposed in different layers.

The via 113 may have a tapered shape having a narrowing width along the thickness direction. For example, as shown in the drawing, the via 113 may have a tapered shape having a narrowing width in a direction from top to bottom. However, the inventive concepts are not limited thereto, and the via 113 may have a circular cylinder shape having a uniform width along the thickness direction, and may have a tapered shape having a narrowing width in a direction from bottom to top.

A conductive material may be used as the material of each of the wire layer 112 and the via 113, and for example, aluminum (Al), copper (Cu), gold (Au), silver (Ag), platinum (Pt), tin (Sn), chromium (Cr), palladium (Pd), lead (Pb), titanium (Ti), or any alloy thereof may be used, but are not limited thereto.

In addition, the wire layer 112 and the via 113 may be integrally formed with each other, such that there is not a boundary between them, for example such that the wire layer 112 and the via 113 may be separate portions of a single, unitary piece of material. For example, the wire layer 112 and the via 113 may be integrally formed by forming a via hole in the insulation layer 111, forming a seed layer on a bottom surface and a wall surface of the via hole and the insulation layer 111, and then, forming a plated layer on the seed layer.

The semiconductor chip 120 may be disposed on one surface (also referred to herein as a first surface 140a) of the first redistribution layer structure 140 and in the through-hole 110h of the support substrate 110, and may be electrically connected to the redistribution layer 142 of the first redistribution layer structure 140.

The semiconductor chip 120 may include a body 121, and a connection pad 122.

The body 121 may include a semiconductor substrate including silicon (Si), germanium (Ge), gallium arsenide (GaAs), silicon carbide (Sic), and the like, a plurality of individual devices, an internal circuit, and an interlayer insulation layer.

The connection pad 122 may electrically connect the semiconductor chip 120 to other components such as the first redistribution layer structure 140. A conductive material such as aluminum (Al), copper (Cu), and the like may be used as a material of the connection pad 122.

As shown in the drawing, the semiconductor chip 120 may be disposed in a face-down direction such that the connection pad 122 faces the first redistribution layer structure 140, and on the contrary, may be disposed in a face-up direction such that the connection pad 122 faces the second redistribution layer structure 180.

As will be described later, the semiconductor chip 120 may be attached on an adhesive film 10 together with the support substrate 110, and accordingly, one surface of the semiconductor chip 120 may be coplanar with one surface of the support substrate 110.

The type of the semiconductor chip 120 is not particularly limited, and may be a central processing unit (CPU), a graphic processing unit (GPU), an application processor (AP), a logic chip, a volatile or non-volatile memory chip, a system-on-chip (SOC), and the like.

The encapsulating material 130 may fill at least a portion of the through-hole 110h, and encapsulate the semiconductor chip 120. In addition, the encapsulating material 130 may extend onto the support substrate 110, and may cover an upper surface of the support substrate 110 together with an upper surface of the semiconductor chip 120. The encapsulating material 130 may be formed as a thermosetting resin such as epoxy molding compound (EMC) and epoxy resin, but is not limited thereto.

The first redistribution layer structure 140 may rewire the connection pad 122 of the semiconductor chip 120, and may electrically connect the semiconductor chip 120 to the wire layer 112 and the under-bump metal layer 152. The first redistribution layer structure 140 may be disposed to face the connection pad 122 of the semiconductor chip 120, and may be disposed to extend onto a lower surface of the support substrate 110.

The first redistribution layer structure 140 may include the insulation layer 141, the redistribution layer 142, and a via 143.

The insulation layer 141 may include a photoimageable dielectric (PID). When the insulation layer 141 includes a photoimageable dielectric, the insulation layer 141 having a thin thickness and the via 143 having a fine pitch may be formed. However, the inventive concepts are not limited thereto, and as a material of the insulation layer 141, the same as in the insulation layer 111, a thermosetting resin such as epoxy resin, a thermoplastic resin such as polyimide, pre-preg, Ajinomoto build-up film (ABF), and the like may be used.

The redistribution layer 142 may rewire the connection pad 122 of the semiconductor chip 120, and may be electrically connected to the wire layer 112 and the under-bump metal layer 152. The redistribution layer 142 may perform various functions depending on the design, and for example, may include a signal pattern, a power pattern, a ground pattern, and the like.

The via 143 may penetrate the insulation layer 141 to interconnect the redistribution layers 142 disposed in different layers. In addition, the via 143 may include the via 143 penetrating the insulation layer 141 and contacting the connection pad 122 of the semiconductor chip 120. As will be described later, the first redistribution layer structure 140 may be formed by using the chip first method, i.e., after disposing the semiconductor chip 120 in the through-hole 110h of the support substrate 110 and then encapsulating the semiconductor chip 120 by the encapsulating material 130, and through these processes, the via 143 contacting the connection pad 122 of the semiconductor chip 120 may be formed.

The via 143 may have a tapered shape having a narrowing width along the thickness direction. For example, as shown in the drawing, the via 143 may have a tapered shape having a narrowing width in a direction from bottom to top. However, the inventive concepts are not limited thereto, and the via 143 may have a circular cylinder shape having a uniform width along the thickness direction. In some example embodiments, when the chip last method is used, in which the first redistribution layer structure 140 is formed first, and then the semiconductor chip 120 is disposed on the first redistribution layer structure 140, the via 143 may have a tapered shape having a narrowing width in a direction from top to bottom.

A conductive material may be used as the material of each of the redistribution layer 142 and the via 143, and for example, aluminum (Al), copper (Cu), gold (Au), silver (Ag), platinum (Pt), tin (Sn), chromium (Cr), palladium (Pd), lead (Pb), titanium (Ti), or any alloy thereof may be used, but are not limited thereto.

In addition, the redistribution layer 142 and the via 143 may be integrally formed with each other, such that there is not a boundary between them, for example such that the redistribution layer 142 and the via 143 may be separate portions of a single, unitary piece of material. For example, the redistribution layer 142 and the via 143 may be integrally formed by forming a via hole in the insulation layer 141, forming a seed layer on a bottom surface and a wall surface of the via hole and the insulation layer 141, and then, forming a plated layer on the seed layer.

The under-bump structure 150 may be disposed on a second surface (140b) of first redistribution layer structure 140 that is an opposite surface of a first surface (140a) of the first redistribution layer structure 140 on which the support substrate 110 and the semiconductor chip 120 are disposed.

The under-bump structure 150 may include the protective layer 151 having a trench T, the under-bump metal layer 152, and a via 153.

The protective layer 151 may be disposed on the first redistribution layer structure 140, and the protective layer 151 may protect the first redistribution layer structure 140 from physical, chemical, mechanical damages.

An insulative material may be used as a material of the protective layer 151, and for example, Ajinomoto build-up film (ABF) may be used. However, the inventive concepts are not limited thereto, and a thermosetting resin such as epoxy resin, a thermoplastic resin such as polyimide, pre-preg, and the like may be used as the material of the protective layer 151. In some example embodiments, solder resist (SR) may be used as the material of the protective layer 151. The protective layer 151 may include an inorganic filler such as silica SiO₂, and a reinforcing material such as glass fiber.

The protective layer 151 may include one or more inner surfaces 151s at least partially defining a trench T. The trench T may penetrate the protective layer 151 in the thickness direction around the region where the electronic element 160 of the protective layer 151 is disposed, and may control bleeding of the underfill member 170.

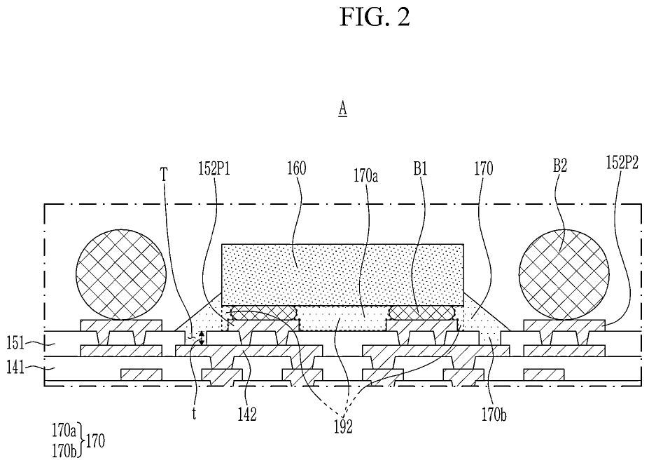

FIG. 2 is an enlarged view of region A of FIG. 1 according to some example embodiments. Referring to FIG. 2, a thickness t of smaller T may be 20 μm to 30 μm. When a thickness of a trench is excessively thin (e.g., less than 20 μm), the bleeding control of the underfill member 170 may be difficult, and when it is excessively thick (e.g., greater than 30 μm), it may be difficult to efficiently fill the underfill member 170 into a space defined between the under-bump structure 150 and the electronic element 160. Accordingly, a thickness of the trench T may be preferably controlled in the above-mentioned range.

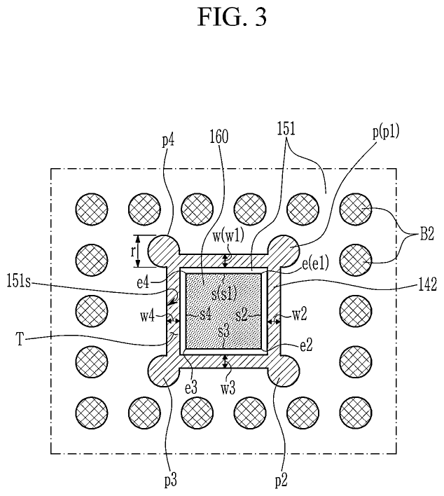

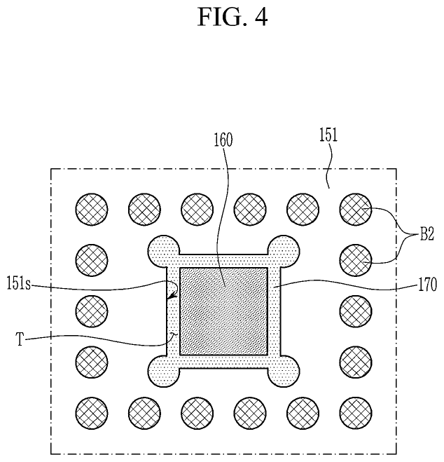

FIG. 3 is a bottom view of region A excluding the underfill member of FIG. 1 according to some example embodiments. FIG. 4 is a bottom view of region A of FIG. 1 according to some example embodiments.

Referring to FIG. 3 and FIG. 4, the trench T may surround (e.g., partially or entirely surround) the electronic element 160, in a plan view, and may have one or more protrusion portions p protruding outward from the electronic element 160 in a region surrounding an edge e of the electronic element 160.

Since the trench T surrounds the electronic element 160 in a plan view, the underfill member 170 may be prevented from bleeding in the outer side direction of the electronic element 160.

When a distance between an interior circumference and an exterior circumference of the trench T, in a region surrounding side surface s forming the edge e of the electronic element 160, is referred to as a width w of the trench T, the width w of the trench T may be 100 μm to 200 μm. When the width w of the trench T is excessively narrow (e.g., smaller than 100 μm), the bleeding control of the underfill member 170 may be difficult, and when it is excessively wide (e.g., greater than 200 μm), a space for arranging the under-bump metal layer 152 and a conductive bump B2 may be limited. Accordingly, the width w of the trench T may be preferably controlled within the above-mentioned range.

In each region surrounding a first one side surface s (e.g., s1) and a second one side surface s (e.g., s2) forming the edge e (e.g., e1) of the electronic element 160, the width w of the trench T may be the same or substantially the same. Here, substantially the same means including errors in the manufacturing process and measurement errors (e.g., widths w1 and w2 being within 10% tolerance or margin in of each other). For example, a width w1 of the trench T in a region surrounding a first side surface s1 forming a first edge e1 of the electronic element 160 may be the same as a width w2 of the trench T in a region surrounding a second side surface s2 that is the second one side surface forming the first edge e1. As another example, a width w3 of the trench T in a region surrounding third side surface s3 forming a third edge e3 of the electronic element 160 may be the same as a width w4 of the trench T in region surrounding a fourth side surface s4 that is the second one side surface forming the third edge e3. Through such a structure, the underfill member 170 drawn into the protrusion portion p may uniformly flow in both directions, thereby maximizing controllability of flow of the underfill member 170.

Since the trench T has the protrusion portion p protruding outward from the electronic element 160 in a region surrounding the edge e of the electronic element 160, the underfill member 170 gathered to the region surrounding the edge e of the electronic element 160 may be prevented from leaking out to the protective layer 151.

The protrusion portion p may include a plurality of protrusion portions p disposed in regions surrounding the edge e of the electronic element 160, respectively. For example, the protrusion portion p may include a first protrusion portion p1 disposed in a region surrounding the first edge e1 of the electronic element 160, a second protrusion portion p2 disposed in a region surrounding a second edge e2, a third protrusion portion p3 disposed in a region surrounding the third edge e3, and a fourth protrusion portion p4 disposed in a region surrounding a fourth edge e4.

The protrusion portion P may include a curved surface. Preferably, the protrusion portion P may have a circular arc shape, in a plan view. When the protrusion portion P includes a curved surface or has a circular arc shape in a plan view, controllability of flow of the underfill member 170 gathered from a region surrounding two side surfaces s forming the edge e of the electronic element 160 of the trench T to the protrusion portion p may be increased, optimized, or maximized.

A maximum distance r between wall surfaces of the curved surface may be 200 μm to 300 μm. When the protrusion portion p has a circular arc shape in a plan view, a maximum distance between wall surfaces of the curved surface may be coincide with a diameter of a circle. When the maximum distance r between wall surfaces of the curved surface is excessively small (e.g., smaller than 200 μm), controllability of flow of the underfill member 170 gathered in the protrusion portion P may be difficult, and when it is excessively large (e.g., greater than 300 μm), a space for arranging the under-bump metal layer 152 and the conductive bump B2 may be limited. Accordingly, the maximum distance r between wall surfaces of the curved surface may be preferably controlled within the above-mentioned range.

At the time of processing the trench T, the redistribution layer 142 may serve as a process stop layer, and accordingly, the redistribution layer 142 may be exposed through the trench T. Through such a structure, the trench T may be easily controlled to have a uniform thickness T over all regions, and by deeply penetrating the protective layer 151, the bleeding control of the underfill member 170 may be maximized. The redistribution layer 142 exposed through the trench T may be the redistribution layer 142 disposed lowermost among a plurality of redistribution layers 142 and covered by the protective layer 151.

The under-bump metal layer 152 may be electrically connected to the redistribution layer 142, and connection reliability between the first redistribution layer structure 140 and the conductive bump B2 may be increased.

As shown in the drawing, the under-bump metal layer 152 may be disposed on the protective layer 151. In some example embodiments, the under-bump metal layer 152 may be at least partially buried in the protective layer 151, and for example, at least a portion of a side surface of the under-bump metal layer 152 may be covered by the protective layer 151.

The under-bump metal layer 152 may include a first under-bump pad 152P1 and a second under-bump pad 152P2. The electronic element 160 may be disposed on the first under-bump pad 152P1, and the conductive bump B2 may be disposed on the second under-bump pad 152P2.

The via 153 may penetrate the protective layer 151 to interconnect the redistribution layer 142 and the under-bump metal layer 152. The via 153 may fully fill the via hole formed in the protective layer 151, but may have a uniform thickness along a wall surface and a bottom surface of the via hole, such that the interior of the via hole may be open. When the via 153 has a uniform thickness, the under-bump metal layer 152 may have a structure recessed into an inner side of the protective layer 151 together with the via 153.

A conductive material may be used as the material of each of the under-bump metal layer 152 and the via 153, and for example, copper (Cu), aluminum (Al), nickel (Ni), titanium (Ti), chromium (Cr) or any alloy thereof may be used, but are not limited thereto. The under-bump metal layer 152 and the via 153 may be integrally formed with each other, such that there is not a boundary between them, for example such that the under-bump metal layer 152 and the via 153 may be separate portions of a single, unitary piece of material. In addition, the under-bump metal layer 152 and the via 153 may include a plurality of metal layers that include above-mentioned materials, respectively.

The electronic element 160 may be disposed on the under-bump structure 150, and may be electrically connected to the under-bump metal layer 152.

The electronic element 160 may be a surface mounting component part mounted on the under-bump structure 150 by a surface mount technology (SMT).

The electronic element 160 may be a passive element such as an inductor or a capacitor such as an integrated stacked capacitor (ISC). As is known, an integrated stack capacitor may include a plurality of trenches including an insulation layer disposed between the plurality of metal layers and the plurality of metal layers storing charges. When the electronic element 160 is an integrated stack capacitor, the electronic element 160 may provide excellent capacity and performance, high reliability, and design flexibility.

For surface mounting of the electronic element 160, the semiconductor package 100A may include a conductive bump B1. The conductive bump B1 may be disposed between the under-bump metal layer 152 and the electronic element 160, and covered by the underfill member 170. A conductive material may be used as a material of the conductive bump B1, and for example, the conductive bump B1 may be a solder ball or metal pillar.

The underfill member 170 may alleviate stress applied to the conductive bump B1 due to difference in the coefficient of thermal expansion between components, physical impact, or the like and prevent defect caused thereby, such that reliability of the electronic element 160 may be secured.

The underfill member 170 may fill between the under-bump structure 150 and the electronic element 160 and at least a portion of the trench T, respectively. For example, as shown in at least FIGS. 1 and 2, the underfill member 170 may fill at least a portion of a space 192 at least partially defined between surfaces of the under-bump structure 150 and the electronic element 160 in the thickness direction which may extend perpendicular to at least one of the first surfaces 140a or the second surface 140b of the first redistribution layer structure 140 and may fill at least a portion of the trench T. For example, the underfill member 170 may include a first portion 170a between the under-bump structure 150 and the electronic element 160 in the thickness direction, and thus partially or entirely filling the space 192 between the under-bump structure 150 and the electronic element 160 in the thickness direction, and a second portion 170b filling at least a portion of the trench T, where the first and second portions 170a and 170b may be separate portions of a single, unitary piece of material comprising the material of the underfill member 170. The underfill member 170 (e.g., at least a portion thereof) may be disposed between (e.g., directly or indirectly between) the under-bump structure 150 and the electronic element 160 to cover the conductive bump B1, and at the time of forming the underfill member 170, the material bleeding to an outer side of the electronic element 160 (e.g., a second portion 170b of the underfill member 170 extending to a region of space that is not between the electronic element and the under-bump structure 150 in the thickness direction which may extend perpendicular to at least one of the first surfaces 140a or the second surface 140b of the first redistribution layer structure 140, and/or to a region of space that is exposed from the electronic element 160 in the thickness direction) may flow into the trench T so as to fill at least a portion of the trench T, for example as shown in at least FIG. 4.

A material of the underfill member 170 may be based on a thermosetting resin such as epoxy resin, and may include a silica filler. The underfill member 170 may be formed by implanting the underfill material between the under-bump structure 150 and the electronic element 160 through a nozzle or the like, and curing it.

The semiconductor package 100A may include the conductive bump B2 for electrically connecting the semiconductor package 100A to other components such as a main board. The conductive bump B2 may be disposed on the under-bump metal layer 152. A conductive material may be used as a material of the conductive bump B2, and for example, the conductive bump B2 may be a solder ball or metal pillar.

The second redistribution layer structure 180 may be disposed on the encapsulating material 130. The second redistribution layer structure 180 may be electrically connected to the wire layer 112 of the support substrate 110, and may electrically connect the semiconductor package 100A to other components disposed in an upper side of the semiconductor package 100A.

The second redistribution layer structure 180 may include the insulation layer 181, the redistribution layer 182, and a via 183. The numbers (e.g., quantities) of insulation layers 181, redistribution layers 182, and vias 183 are not particularly limited, and the second redistribution layer structure 180 may include a larger or smaller number of insulation layers 181, redistribution layers 182, and vias 183 than as shown in the drawing.

An insulative material may be used as a material of the insulation layer 181, and for example, Ajinomoto build-up film (ABF) may be used. However, the inventive concepts are not limited thereto, and a thermosetting resin such as epoxy resin, a thermoplastic resin such as polyimide, pre-preg, and the like may be used as the material of the insulation layer 181.

The redistribution layer 182 may be connected to the wire layer 112, so as to rewire the wire layer 112 and components electrically connected thereto. The redistribution layer 182 may perform various functions depending on the design, and for example, may include a signal pattern, a power pattern, a ground pattern, and the like.

The via 183 may penetrate the insulation layer 181 to interconnect the redistribution layers 182 disposed in different layers, or penetrate the encapsulating material 130 to interconnect the wire layer 112 and the redistribution layer 182. As shown in the drawing, the via 183 may include a deep via penetrating the insulation layer 181 and the encapsulating material 130 to interconnect the wire layer 112 and the redistribution layer 182, but is not limited thereto.

The via 183 may have a tapered shape having a narrowing width along the thickness direction. For example, as shown in the drawing, the via 183 may have a tapered shape having a narrowing width in a direction from top to bottom. However, the inventive concepts are not limited thereto, and the via 183 may have a circular cylinder shape having a uniform width along the thickness direction.

A conductive material may be used as the material of each of the

redistribution layer 182 and the via 183, and for example, aluminum (Al), copper (Cu), gold (Au), silver (Ag), platinum (Pt), tin (Sn), chromium (Cr), palladium (Pd), lead (Pb), titanium (Ti), or any alloy thereof may be used, but are not limited thereto.

In addition, the redistribution layer 182 and the via 183 may be integrally formed with each other, such that there is not a boundary between them. For example, the redistribution layer 182 and the via 183 may be integrally formed by forming a via hole in the insulation layer 181, forming a seed layer on a bottom surface and a wall surface of the via hole and the insulation layer 181, and then, forming a plated layer on the seed layer.

The semiconductor package 100A may further include the protective layer 190 disposed on the second redistribution layer structure 180 and configured to protect the second redistribution layer structure 180 from physical, chemical, mechanical damages. The protective layer 190 may have an opening exposing at least a portion of the redistribution layer 182.

An insulative material may be used as a material of the protective layer 190, and for example, Ajinomoto build-up film (ABF) may be used. However, the inventive concepts are not limited thereto, and a thermosetting resin such as epoxy resin, a thermoplastic resin such as polyimide, pre-preg, and the like may be used as the material of the protective layer 190. In some example embodiments, solder resist (SR) may be used as the material of the protective layer 190.

According to the present inventive concepts, by forming the trench T in the protective layer 151 of the semiconductor package 100A, bleeding of the underfill material (e.g., material at least partially comprising the underfill member 170), for example bleeding of such underfill outward from the electronic element 160 so as to be exposed from the electronic element 160 in plan view and/or in the thickness direction, may be controlled, and accordingly, mounting defects of the electronic element 160 resulting from uncontrolled bleeding of the underfill material outward from the electronic element 160 may be reduced, minimized, or prevented, and the semiconductor package 100A having improved reliability may be provided.

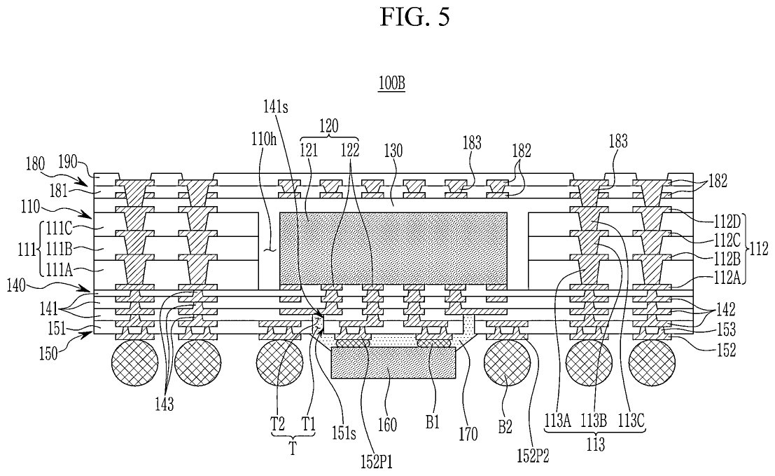

FIG. 5 is a cross-sectional view of a semiconductor package according to some example embodiments of the present inventive concepts.

Referring to the drawing, a semiconductor package 100B according to some example embodiments of the present inventive concepts slightly differs from the semiconductor package 100A according to some example embodiments of the present inventive concepts in the structure of the trench T.

In a semiconductor package 100B, the insulation layer 141 of the first redistribution layer structure 140 may have a second trench T2 extending from a first trench T1 included in (e.g., defined by one or more inner surfaces of) the protective layer 151 of the under-bump structure 150 and integrated thereto. The first trench T1 and the second trench T2 may be formed through the same process, and widths of the first trench T1 and the second trench T2 may be the same.

At the time of processing the trench T, the redistribution layer 142 serving as a process stop layer and exposed through the trench T may be one of the redistribution layers 142 buried in the insulation layer 141.

When the bleeding control of the underfill member 170 is difficult by using only the first trench T1 of the protective layer 151 due to the thickness of the protective layer 151 or the like, the bleeding control of the underfill member 170 may be improved, by forming the second trench T2, extending from the first trench T1 and integrated thereto, in the insulation layer 141 (e.g., such that one or more inner surfaces 141s of the insulation layer 141 at least partially define the second trench T2, and such that the second trench T2 may be directly adjacent and open to the first trench T1).

Since the description of other components is the same as that specifically described in the description of the semiconductor package 100A according to some example embodiments of the present inventive concepts, detailed description of these components will be omitted.

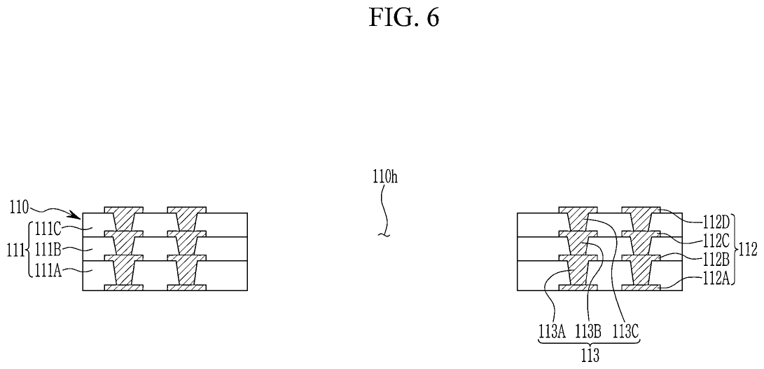

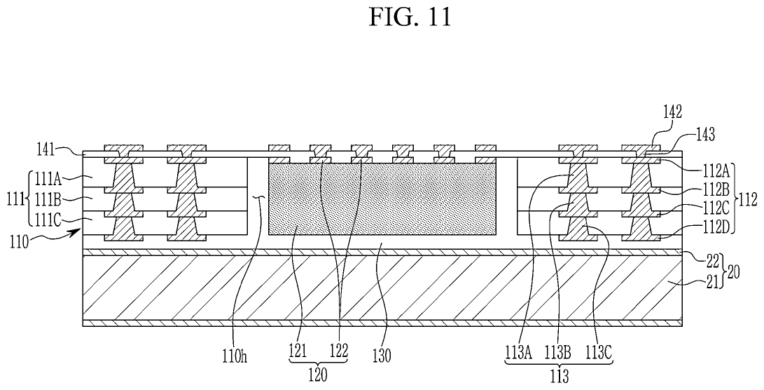

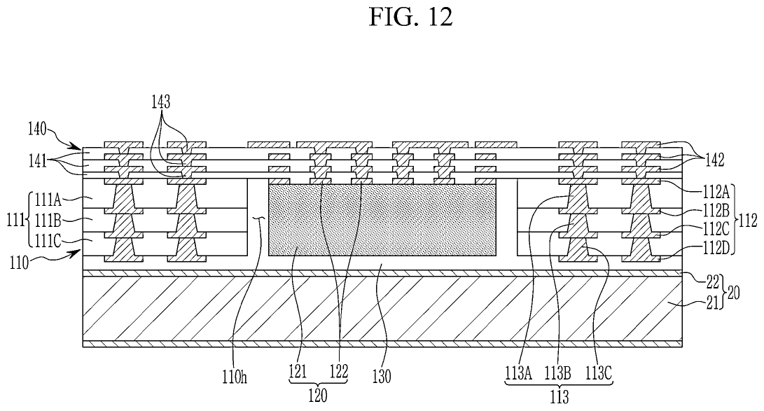

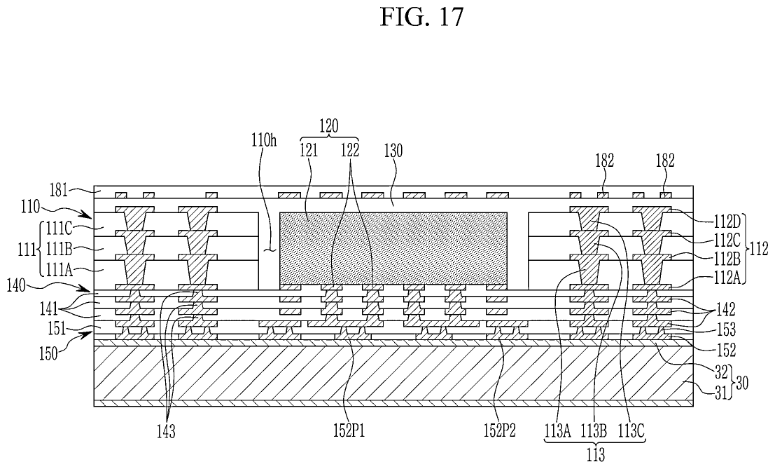

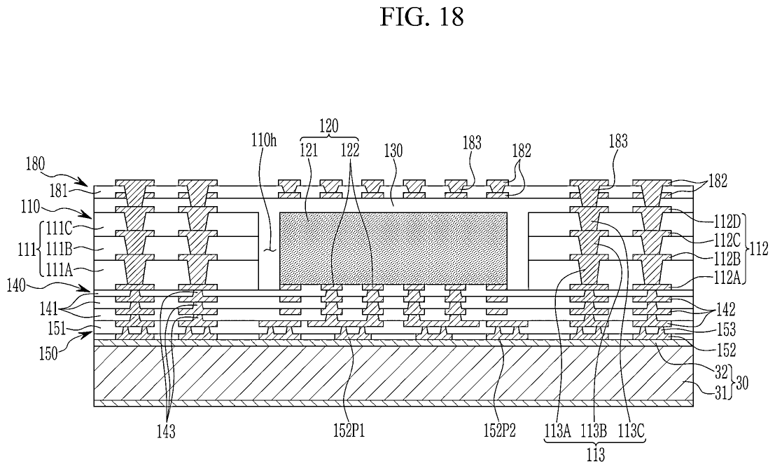

FIGS. 6, 7, 8, 9, 10, 11, 12, 13, 14, 15, 16, 17, 18, 19, 20, 21, and 22 are manufacturing process diagrams of a semiconductor package according to some example embodiments of the present inventive concepts.

Referring to FIG. 6, firstly, the support substrate 110 having the through- hole 110h is prepared. The through-hole 110h may be formed by using, for example, a laser drill, a mechanical drill, a sand blast method, and the like.

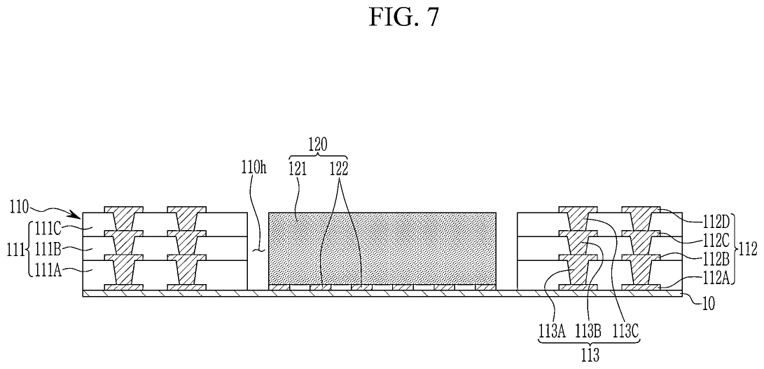

Subsequently, referring to FIG. 7, the semiconductor chip 120 is prepared, the support substrate 110 is disposed on the adhesive film 10, and then the semiconductor chip 120 is disposed in the through-hole 110h. As the adhesive film 10 may use, for example, an adhesive tape of which adhesive strength is weakened by heat treatment or ultraviolet irradiation. The semiconductor chip 120 may be disposed in the face-down format such that the connection pad 122 faces the adhesive film 10.

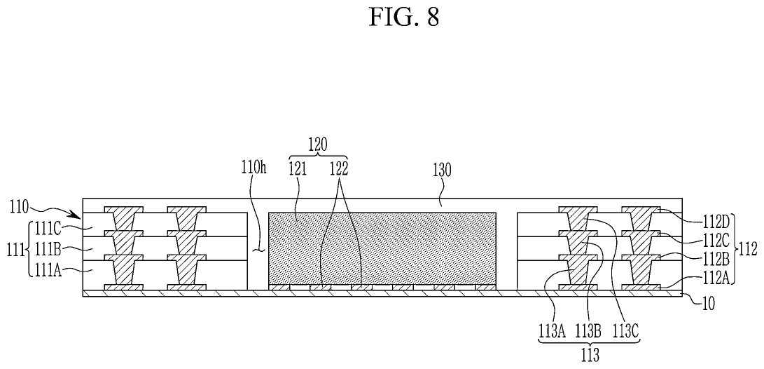

Subsequently, referring to FIG. 8, the semiconductor chip 120 is encapsulated by the encapsulating material 130. The process of encapsulating the semiconductor chip 120 by the encapsulating material 130 may be performed by compression molding, transfer molding, or the like.

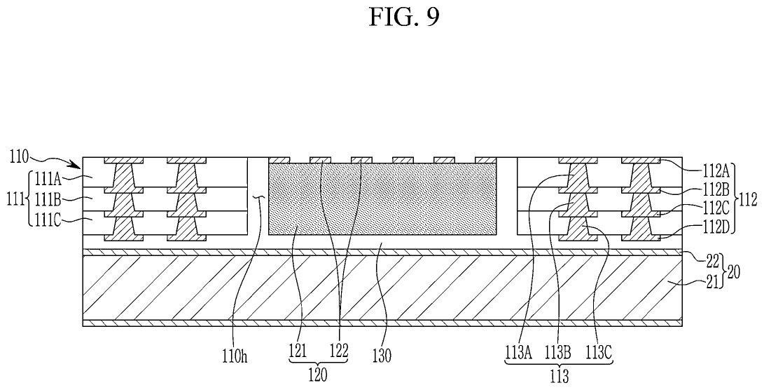

Subsequently, referring to FIG. 9, a first carrier film 20 is attached on the encapsulating material 130, and the adhesive film 10 is removed. The first carrier film 20 may be, for example, a copper clad laminate such as DCF including an insulation layer 21 and a metal layer 22 disposed on at least one surface of the insulation layer 21. The adhesive film 10 may be removed by the heat treatment or ultraviolet irradiation.

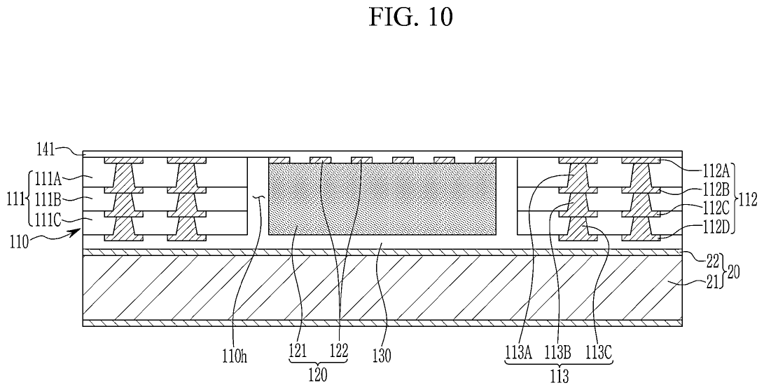

Subsequently, referring to FIGS. 10, 11, and 12, the first redistribution layer structure 140 may be formed by repeatedly forming the insulation layer 141, the redistribution layer 142, and the via 143 on the semiconductor chip 120 and the support substrate 110. The insulation layer 141, the redistribution layer 142, and the via 143 may be formed by coating a photoimageable dielectric, forming a via hole exposing the connection pad 122 and the wire layer 112 through an exposing and developing process, and then forming the redistribution layer 142 and the via 143. The redistribution layer 142 may be electrically connected to the semiconductor chip 120 and the wire layer 112 through the via 143.

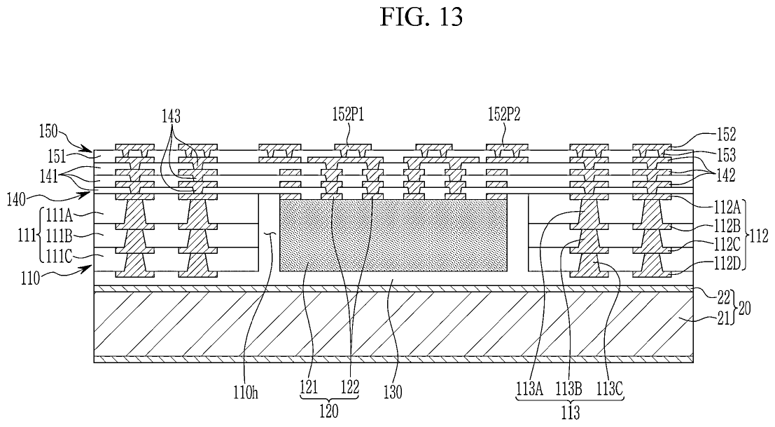

Subsequently, referring to FIG. 13, the protective layer 151 may be formed by laminating the insulating material on the first redistribution layer structure 140, and the under-bump metal layer 152 and the via 153 electrically connected to the redistribution layer 142 on the protective layer 151 may be formed.

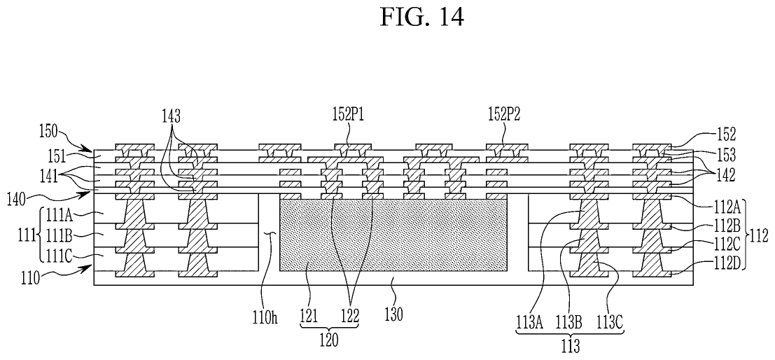

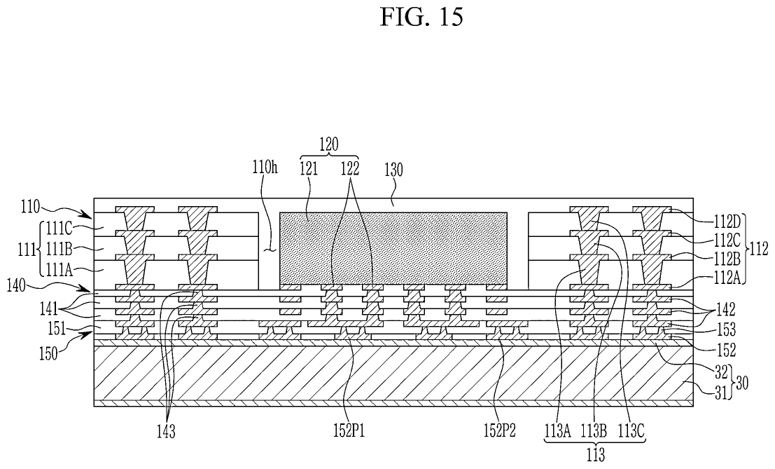

Subsequently, referring to FIG. 14 and FIG. 15, the first carrier film 20 is removed, and a second carrier film 30 is attached on the under-bump structure 150. Like the first carrier film 20, the second carrier film 30 may be a copper clad laminate such as DCF including an insulation layer 31 and a metal layer 32 disposed on at least one surface of the insulation layer 31.

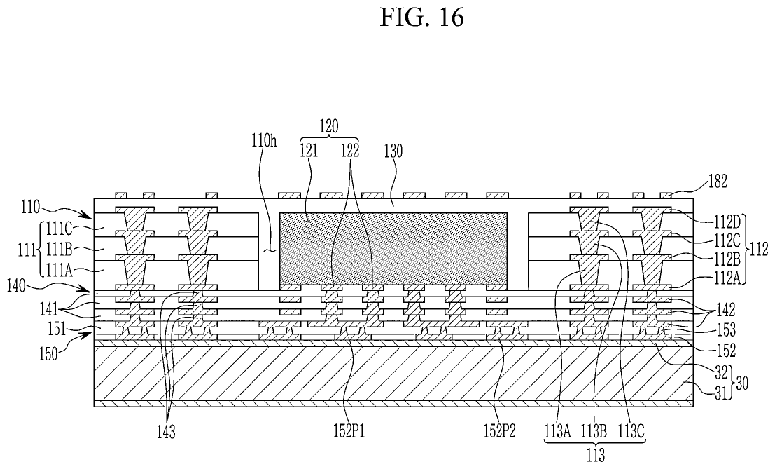

Subsequently, referring to FIGS. 16, 17, and 18, the second redistribution layer structure 180 on the encapsulating material 130 may be formed. The second redistribution layer structure 180 may be formed by forming a second redistribution layer 182 on the encapsulating material 130, for example, by a modified semi-additive process (MASP) method, forming the insulation layer 181, forming a deep via hole penetrating the insulation layer 181 and the encapsulating material 130 to expose the wire layer 112 and a via hole penetrating the insulation layer 181 to expose the second redistribution layer 182, and then forming the via 183 and a second redistribution layer 182 by a Semi-Additive Process (SAP) method.

At this time, on the second redistribution layer 182, an additional metal layer for preventing corrosion and oxidation of the second redistribution layer 182, improving reliability, or the like may be disposed be. For example, on the second redistribution layer 182, a nickel layer and a metal layer may be disposed by sequentially plating nickel and gold.

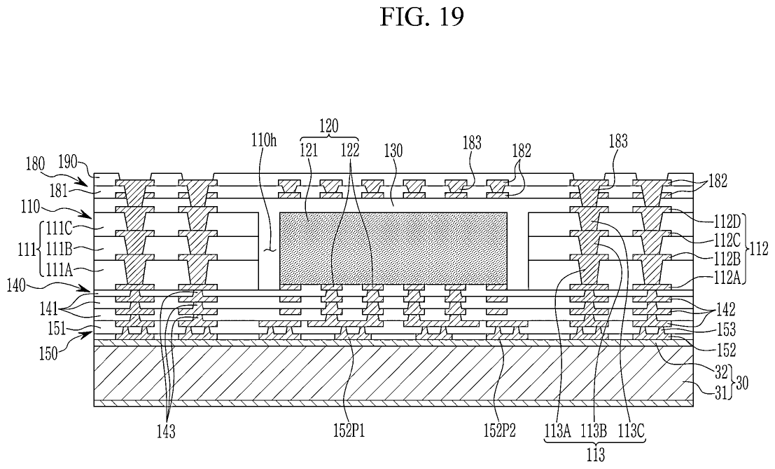

Subsequently, referring to FIG. 19, the protective layer 190 on the second redistribution layer structure 180 may be formed. Through laser processing or the like, an opening exposing at least a portion of the second redistribution layer 182 may be formed in the protective layer 190.

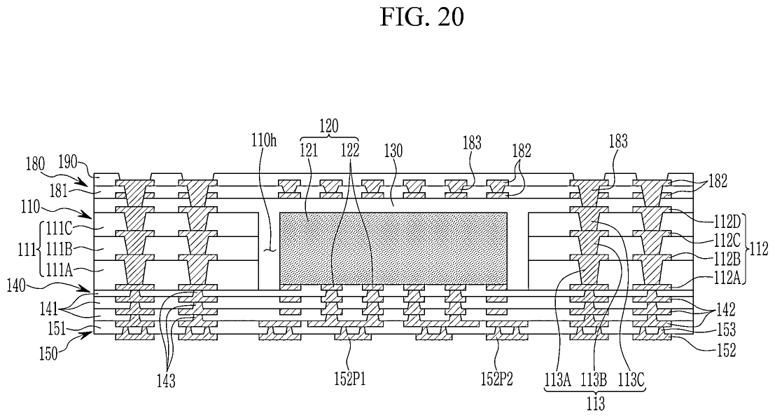

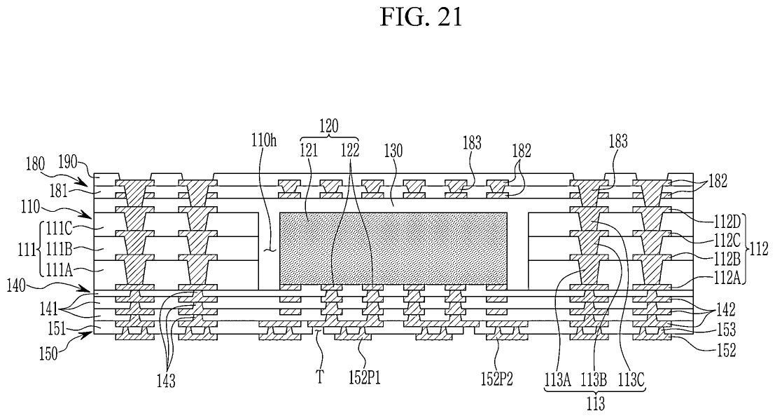

Subsequently, referring to FIG. 20 and FIG. 21, by removing the second carrier film 30 and forming the trench T in the protective layer 151, the under-bump structure 150 including the protective layer 151 having the trench T may be formed. The trench T may be formed by laser processing, and the redistribution layer 142 may serve as a process stop layer. Therefore, the redistribution layer 142 may be exposed through the trench T.

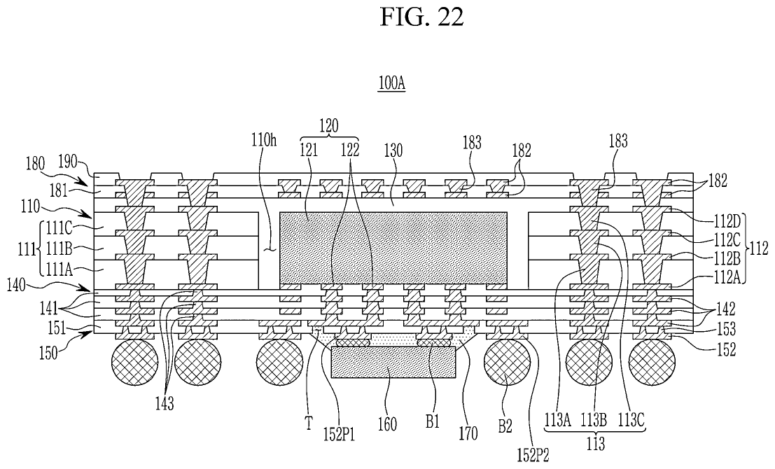

Finally, referring to FIG. 22, the conductive bump B2 is attached on the under-bump structure 150, the electronic element 160 is disposed, and then the underfill member 170 is formed. The conductive bump B2 may be attached on the second under-bump pad 152P2, and the electronic element 160 may be surface mounted on the first under-bump pad 152P1 through the conductive bump B1.

While the inventive concepts have been described in connection with what is presently considered to be practical example embodiments, it is to be understood that the inventive concepts are not limited to such example embodiments, but, on the contrary, are intended to cover various modifications and equivalent arrangements included within the spirit and scope of the appended claims.

What is claimed is:

1. A semiconductor package, comprising:
a redistribution layer structure including a redistribution layer;
a semiconductor chip on a first surface of the redistribution layer structure;
an under-bump structure on a second surface of the redistribution layer structure that is an opposite surface of the first surface of the redistribution layer structure, the under-bump structure including a protective layer having a trench and an under-bump metal layer;
an electronic element on the under-bump structure; and
an underfill member filling at least a portion of a space defined between the under-bump structure and the electronic element and filling at least a portion of the trench,
wherein, in a plan view, the trench surrounds the electronic element, and the trench includes a protrusion portion protruding outward from the electronic element in a region surrounding an edge of the electronic element.

2. The semiconductor package of claim 1, wherein the protrusion portion includes a curved surface.

3. The semiconductor package of claim 2, wherein the protrusion portion has a circular arc shape, in the plan view.

4. The semiconductor package of claim 2, wherein a maximum distance between wall surfaces of the curved surface is 200 μm to 300 μm.

5. The semiconductor package of claim 1, wherein a thickness of the trench is 20 μm to 30 μm.

6. The semiconductor package of claim 1, wherein
a distance between an interior circumference and an exterior circumference of the trench in a region surrounding side surface forming the edge of the electronic element is a width of the trench, and
the width of the trench is 100 μm to 200 μm.

7. The semiconductor package of claim 6, wherein, in regions surrounding a first side surface and a second side surface forming the edge of the electronic element, the width of the trench is substantially same.

8. The semiconductor package of claim 1, wherein the protrusion portion includes a plurality of protrusion portions in regions surrounding the edge of the electronic element, respectively.

9. The semiconductor package of claim 1, wherein the electronic element is an integrated stack capacitor (ISC).

10. A semiconductor package, comprising:
a first redistribution layer structure including a first insulation layer and a first redistribution layer;
a semiconductor chip on a first surface of the first redistribution layer structure and electrically connected to the first redistribution layer;
an encapsulating material encapsulating the semiconductor chip;
an under-bump structure on a second surface of the first redistribution layer structure that is an opposite surface of the first surface of the first redistribution layer structure, the under-bump structure including a first protective layer having a first trench and an under-bump metal layer electrically connected to the first redistribution layer;
an electronic element on the under-bump structure, the electronic element electrically connected to the under-bump metal layer; and
an underfill member filling at least a portion of a space defined between the under-bump structure and the electronic element and filling at least a portion of the first trench,
wherein the first redistribution layer is exposed through the first trench.

11. The semiconductor package of claim 10, wherein:
the first insulation layer comprises a second trench extending from the first trench and integrated with the first trench.

12. The semiconductor package of claim 10, wherein the first redistribution layer structure further includes a via that penetrates the first insulation layer and contacts a connection pad of the semiconductor chip.

13. The semiconductor package of claim 10, wherein the first insulation layer includes a photoimageable dielectric.

14. The semiconductor package of claim 10, further comprising:
a support substrate on the first surface of the first redistribution layer structure, the support substrate including a second insulation layer and a wire layer electrically connected to the first redistribution layer, the support substrate having a through-hole; and
a second redistribution layer structure on the encapsulating material, and including a third insulation layer and a second redistribution layer electrically connected to the wire layer,
wherein the semiconductor chip is in the through-hole.

15. The semiconductor package of claim 14, further comprising:
a second protective layer on the second redistribution layer structure, and having an opening exposing at least a portion of the second redistribution layer.

16. The semiconductor package of claim 10, further comprising:
a conductive bump between the under-bump metal layer and the electronic element and covered by the underfill member.

17. The semiconductor package of claim 10, wherein:
the under-bump metal layer includes a first under-bump pad and a second under-bump pad;
the electronic element is on the first under-bump pad; and
the semiconductor package further comprises a conductive bump on the second under-bump pad.

18. A manufacturing method for a semiconductor package, the manufacturing method comprising:
preparing a semiconductor chip;
encapsulating the semiconductor chip by an encapsulating material;
forming a redistribution layer structure including a redistribution layer electrically connected to the semiconductor chip on a first surface of the semiconductor chip;
forming an under-bump structure on the redistribution layer structure, the under-bump structure including a protective layer having a trench and an under-bump metal layer;
disposing an electronic element on the under-bump structure so as to be electrically connected to the under-bump metal layer; and
forming an underfill member filling at least a portion of a space defined between the under-bump structure and the electronic element and filling at least a portion of the trench,
wherein forming the under-bump structure includes
forming the protective layer,
forming the under-bump metal layer electrically connected to the redistribution layer on the protective layer, and
forming the trench exposing the redistribution layer in the protective layer.

19. The semiconductor package of claim 18, wherein the trench is formed by laser processing.

20. The semiconductor package of claim 18, wherein in the forming of the trench, the trench is formed to surround the electronic element and to have a protrusion portion protruding outward from the electronic element in a region surrounding an edge of the electronic element, in a plan view.
